(19) United States
(12) Patent Application Publication
(10) Pub. No.: US 2026/0255543 A1
(43) Pub. Date: Aug. 27, 2026

(54) HEAT DISSIPATION MODULE, HEAT SINK, AND SERVER

(71) Applicants: Inventec (Pudong) Technology Corporation, Shanghai (CN); INVENTEC CORPORATION, Taipei (TW)

(72) Inventor: Qidong Li, Shanghai (CN)

(21) Appl. No.: 19/185,294

(22) Filed: Apr. 22, 2025

(30) Foreign Application Priority Data
Feb. 25, 2025 (CN) 202510213845.7

(51) Int. Cl. H05K 7/20

(52) U.S. Cl. CPC H05K 7/20318; H05K 7/20327; H05K 7/20409; H05K 7/208

(57) ABSTRACT

The present disclosure relates to a heat dissipation module, a heat sink, and a server. The heat dissipation module includes: a condenser provided with a gas inlet and a liquid outlet, where the gas inlet and the liquid outlet are respectively arranged at two opposite ends of the condenser in a length direction of the heat dissipation module, a phase change working medium in the condenser flows in a same direction as the length direction and is directed from the gas inlet to the liquid outlet; and at least two heat dissipation assemblies. The at least two heat dissipation assemblies are arranged side by side on a side of the condenser in a width direction of the heat dissipation module. Each heat dissipation assembly includes a heat dissipation plate, a gas outlet pipe and a liquid return pipe.

### CROSS-REFERENCE TO RELATED APPLICATIONS

This application claims priority to Chinese patent application No. 2025102138457, filed on Feb. 25, 2025, the disclosure of which is hereby incorporated by reference in its entirety.

### TECHNICAL FIELD

The present disclosure relates to the technical field of heat dissipation of servers, and in particular, to a heat dissipation module, a heat sink, and a server.

### BACKGROUND

With the rapid development of information technology, a demand for artificial intelligence (AI) computing power is gradually increasing, so a market demand for edge AI servers is also constantly increasing. Correspondingly, the power density of chips used for AI computing is increasing, an increase in power is also accompanied by an increase in heat generation, and electronic components when operating in a high-temperature environment for a long time, will greatly reduce their operational performance and stability.

In a conventional technology, a unidirectional cold plate liquid cooling solution is generally used to provide a heat dissipation service for a chip with a high heat flux density. However, the heat dissipation capacity of unidirectional cold plate liquid cooling is extremely limited, making it difficult to meet the heat dissipation requirements of chips with gradually increasing heat generation. The heat dissipation uniformity is poor, resulting in a large temperature difference between different chips.

### SUMMARY

According to various embodiments of the present disclosure, a heat dissipation module, a heat sink, and a server are provided.

According to a first aspect of the present disclosure, a heat dissipation module may be provided, including:
a condenser provided with a gas inlet and a liquid outlet, where the gas inlet and the liquid outlet are respectively arranged at two opposite ends of the condenser in a length direction of the heat dissipation module, a phase change working medium in the condenser flows in a same direction as the length direction and is directed from the gas inlet to the liquid outlet; and
at least two heat dissipation assemblies. The at least two heat dissipation assemblies are arranged side by side on a side of the condenser in a width direction of the heat dissipation module. Each heat dissipation assembly includes a heat dissipation plate, a gas outlet pipe and a liquid return pipe. An end of the gas outlet pipe is in communication with a gas outlet of the heat dissipation plate, another end of the gas outlet pipe is in communication with the gas inlet. An end of the liquid return pipe is in communication with the liquid outlet, another end of the liquid return pipe is in communication with a liquid return port of the heat dissipation plate. The heat dissipation assembly is configured to be in heat transfer connection with a heat-generating device.

According to a second aspect of the present disclosure, a heat sink may be further provided, including at least two heat dissipation modules as described above. The at least two heat dissipation modules may be arranged side by side in a preset direction.

According to a third aspect of the present disclosure, a server may be further provided, including:
a device module including a heat-generating device; and
the heat sink as described above, where the heat sink may cooperate with the heat-generating device in heat transfer.

### BRIEF DESCRIPTION OF THE DRAWINGS

The accompanying drawings, which constitute a part of the present disclosure, are used to provide a further understanding of the present disclosure, and illustrative embodiments of the present disclosure and descriptions thereof are used to illustrate the present disclosure, but do not constitute an improper limitation to the present disclosure.

In order to clearly illustrate the technical solution of the embodiments of the disclosure, the drawings of the embodiments will be briefly introduced in the following. Obviously, the drawings in the following description are only for some embodiments of the present disclosure. For those of ordinary skill in the art, other drawings can be obtained based on these drawings without creative efforts.

FIG. 1 is a schematic structural view of a heat dissipation module according to an embodiment of the present disclosure.

FIG. 2 is similar to FIG. 1, but from another perspective.

FIG. 3 is a partial exploded view of the heat dissipation module.

FIG. 4 is similar to FIG. 3, but from another perspective.

FIG. 5 is another partial exploded view of the heat dissipation module.

FIG. 6 is a schematic view of a server according to an embodiment of the present disclosure.

### ILLUSTRATIONS FOR REFERENCE NUMERALS

100, heat dissipation module; 10. condenser; 11, gas inlet; 12, liquid outlet; 13, condenser housing; 14, condensing plate; 15, condensing flow channel; 20, heat dissipation assembly; 21, heat dissipation plate; 211, heat dissipation housing; 211a, mounting through hole; 212, heat dissipation fin; 213, mounting member; 214, elastic member; 22, gas outlet pipe; 23, liquid return pipe; 30, gas distributor; 31, gas equalizing groove; 40, water distributor; 41, water distribution groove.

### DETAILED DESCRIPTION

To make the above objects, features, and advantages of the present disclosure more comprehensible, specific implementations of the present disclosure are described in detail below with reference to the accompanying drawings. In the following description, numerous specific details are set forth in order to provide a thorough understanding of the present disclosure. However, the present disclosure can be implemented in many other ways different from those described herein, and those skilled in the art can make similar improvements without departing from the connotation of the present disclosure, so the present disclosure is not limited by the specific embodiments disclosed below.

In the description of the present disclosure, it should be understood that if these terms “center”, “longitudinal”, “transverse”, “length”, “width”, “thickness”, “upper”, “lower”, “front”, “rear”, “left”, “right”, “vertical”, “horizontal”, “top”, “bottom”, “inner”, “outer”, “clockwise”, “counterclockwise”, “axial”, “radial”, “circumferential” and the like appear, the orientation or positional relationship indicated by these terms is based on the orientation or positional relationship shown in the drawings, which are only for the convenience of describing the present disclosure and s implifying the description, rather than indicating or implying that the device or element referred to must have a specific orientation, be constructed and operated in a specific orientation, and therefore cannot be understood as a limitation to the present disclosure.

In addition, if these terms “first” and “second” appear, these terms are only used for descriptive purposes, and cannot be understood as indicating or implying relative importance or implicitly indicating the number of indicated technical features. Thus, features defined by “first” and “second” may explicitly or implicitly include at least one of the features. In the description of the present disclosure, if a term “a plurality of” appears, it means at least two, such as two, three, etc., unless otherwise specifically defined.

In the present disclosure, unless otherwise clearly specified and limited, if the terms “mount”, “connect”, “couple”, “fix”, and the like appear, these terms should be understood in a broad sense. For example, a connection may be a fixed connection, or a detachable connection; or an integral connection; or may be a mechanical connection, or an electrical connection; or may be a direct connection, or an indirect connection through an intermediate medium; or may be an internal communication between two elements or an interaction relationship between two elements, unless otherwise explicitly specified. A person of ordinary skill in the art may understand specific meanings of the foregoing terms in the present disclosure based on a specific situation.

In the present disclosure, unless otherwise expressly specified and limited, if a first feature is described as “above” or “below” a second feature, it means that the first and second features are in direct contact, or the first and second features are in indirect contact through an intermediate medium. Moreover, the first feature being “above”, “over” and “on” the second feature may be that the first feature is directly above or obliquely above the second feature, or merely indicate that the first feature is higher in level than the second feature. That the first feature is “below”, “under” and “beneath” the second feature may mean that the first feature is directly below or obliquely below the second feature, or merely means that the first feature is lower in level than the second feature.

It should be noted that if an element is referred to as being “fixed to” or “disposed on” another element, it can be directly on the other element or intervening elements may also be present. If an element is referred to as being “connected” to another element, it can be directly connected to the other element or intervening elements may be present. If present, the terms “vertical”, “horizontal”, “upper”, “lower”, “left”, “right” and similar expressions used in the present disclosure are only for the purpose of illustration, and do not represent the unique embodiment.

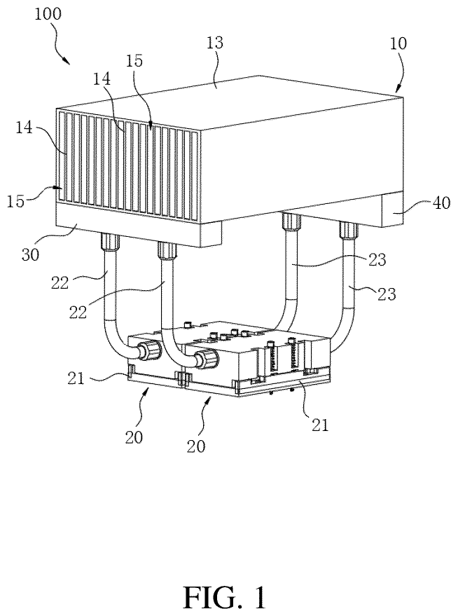

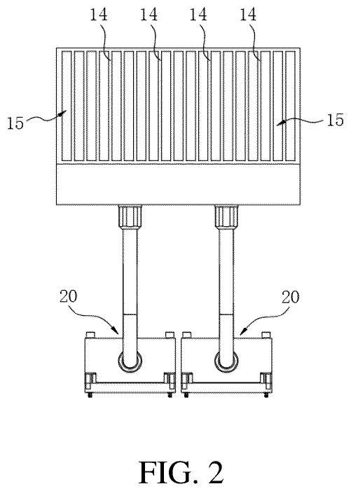

Referring to FIG. 1 and FIG. 2, a heat dissipation module 100 according to an embodiment of the present disclosure is shown, including a condenser 10 and at least two heat dissipation assemblies 20.

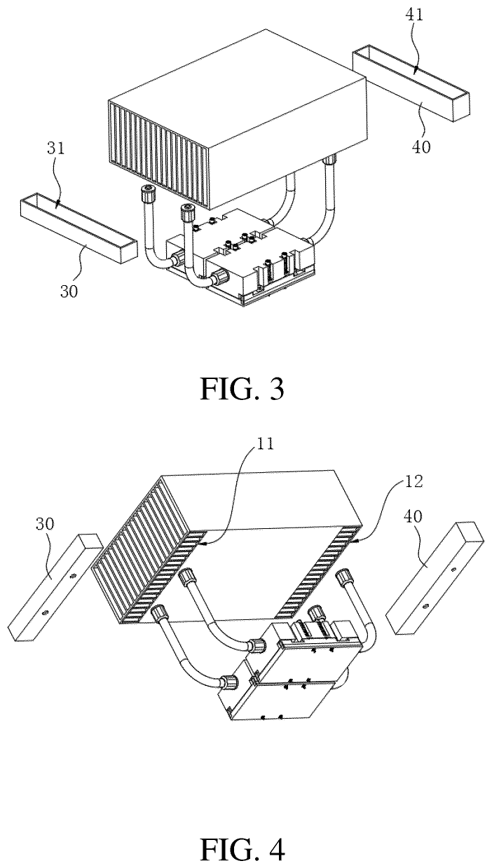

Referring to FIG. 3 and FIG. 4, the condenser 10 is provided with a gas inlet 11 and a liquid outlet 12. The gas inlet 11 and the liquid outlet 12 are respectively arranged at two opposite ends of the condenser 10 in the length direction of the heat dissipation module 100 in one-to-one correspondence. Phase change working medium in the condenser 10 flows in the same direction as the length direction, and is directed from the gas inlet 11 to the liquid outlet 12. The at least two heat dissipation assemblies 20 are arranged side by side on a side of the condenser 10 in the width direction of the heat dissipation module 100. Each heat dissipation assembly 20 includes a heat dissipation plate 21, a gas outlet pipe 22 and a liquid return pipe 23. An end of the gas outlet pipe 22 is in communication with the gas outlet of the heat dissipation plate 21, another end of the gas outlet pipe 22 is in communication with the gas inlet 11. An end of the liquid return pipe 23 is in communication with the liquid outlet 12, another end of the liquid return pipe 23 is in communication with the liquid return port of the heat dissipation plate 21. The heat dissipation assembly 20 is configured to be in heat transfer connection with a heat-generating device.

It should be noted that the phase change working medium in the present disclosure is specifically water. When the water absorbs heat and heats up, it will be vaporized into gas. The gas enters the condenser 10 to exchange heat with the condenser 10, and the heat carried by the gas is absorbed and dissipated, so that the gas will be recondensed into water after the temperature of the gas is reduced.

In other words, the water is continuously switched back and forth between the gas and liquid states in the circulation loop formed by the condenser 10 and the heat dissipation assembly 20, so that heat absorption and cooling can be continuously and continuously implemented on the heat-generating device, thereby ensuring excellent heat dissipation and cooling of the heat-generating device.

Optionally, the heat-generating device in the present disclosure may be, but is not limited to a chip.

In summary, implementing the technical scheme of this embodiment will obtain the following beneficial effects. In the heat dissipation module 100 of this scheme, the heat dissipation assemblies 20 are respectively in heat transfer connection with the corresponding heat-generating devices, then the at least two heat dissipation assemblies 20 are mounted side by side and spaced apart on the side of the condenser 10. The gas outlet pipe 22 of each heat dissipation assembly 20 connects the corresponding heat dissipation plate 21 to the gas inlet 11, and the liquid return pipe 23 connects the corresponding heat dissipation plate 21 with the liquid outlet 12. When high-temperature heat is generated during the working process of the heat-generating device, the heat is transferred to the heat dissipation plate 21, so that the liquid phase change working medium in the heat dissipation plate 21 absorbs the heat and heats up, and is vaporized into high-temperature gas. The high-temperature gas flows into the condenser 10 through the gas outlet pipe 22. As the high-temperature gas flows in the condenser 10, heat exchange occurs between the condenser 10 and the high-temperature gas, so that the condenser 10 can dissipate the heat to the external environment. The gas is cooled and recondensed into the liquid phase change working medium. The liquid phase change working medium flows into the liquid return pipe 23 through the liquid outlet 12, and finally flows back into the heat dissipation plate 21. The above working process is cycled and repeated, so that the heat-generating devices can be continuously cooled, the heat dissipation effect on the heat-generating devices is enhanced, and the heat dissipation requirements are met.

In addition, because the phase change working medium flows in from one end of the condenser 10 and flows out from the other end of the condenser 10, a size in the length direction of the condenser 10 is fully used, a flow path of the phase change working medium is extended, more sufficient heat exchange between the phase change working medium and the condenser 10 is enabled. The heat dissipation assemblies 20 have same heat dissipation performance. Therefore, the heat dissipation effect on the corresponding heat-generating devices is essentially the same, ensuring uniform heat dissipation and avoiding temperature differences between the heat-generating devices.

In the present disclosure, the condenser 10 is of a cuboid structure, and the at least two heat dissipation assemblies 20 are both disposed on one side of a side surface with a largest surface area of the condenser 10. The gas inlet 11 and the liquid outlet 12 are respectively provided at two opposite ends of this side surface in the length direction thereof. Both the gas inlet 11 and the liquid outlet 12 are in communication with the condensation cavity of the condenser 10.

Moreover, the lengths of the gas inlet 11 and the liquid outlet 12 are equal to the width of the condenser 10. in this way, on the one hand, it can be ensured that the gas can effectively fill entire cross section of the condenser 10 as soon as the gas flows into the condenser 10 from the gas inlet 11, thereby ensuring the gas condensation efficiency; on the other hand, the water formed by condensation can also quickly and completely flow out from the liquid outlet 12, thereby preventing water residue and the reduction in the water flow participating in the cooling operation that would affect the overall heat dissipation efficiency of the heat dissipation module 100.

Still referring to FIG. 1, FIG. 3, and FIG. 4, based on the foregoing embodiments, the heat dissipation module 100 further includes a gas distributor 30. The gas distributor 30 is disposed at the gas inlet 11. An end of each gas outlet pipe 22 away from the heat dissipation plate 21 is connected to the gas distributor 30. The high-temperature gas transferred by each gas outlet pipe 22 is converged in the gas distributor 30. The gas distributor 30 distributes and diffuses the high-temperature gas, so that the high-temperature gas can flow into the condenser 10 through the entire gas inlet 11, thereby expanding the heat exchange area to ensure the condensation efficiency.

Specifically, the gas distributor 30 is provided with a gas equalizing groove 31. An opening of the gas equalizing groove 31 is adapted to the size and shape of the gas inlet 11. The opening wall of the opening of the gas equalizing groove 31 is in a sealed connection with an opening wall of the gas inlet 11. Therefore, the high-temperature gas delivered into the gas distributor 30 by the gas outlet pipe 22 is quickly filled into the gas equalizing groove 31, and then flows from the gas equalizing groove 31 to the gas inlet 11, so that the high-temperature gas can be effectively distributed over the entire cross section of the condenser 10.

In addition, in another embodiment, the heat dissipation module 100 further includes a water distributor 40. The water distributor 40 is mounted at the liquid outlet 12. An end of each liquid return pipe 23 away from the heat dissipation plate 21 is connected to the water distributor 40. The water condensed and liquefied by the gas flows into the water distributor 40, and the water distributor 40 shunts the water, so that the amount of water flowing into each liquid return pipe 23 is equivalent, thereby ensuring that the heat dissipation plates 21 have the same heat dissipation effect on the respective heat-generating devices connected thereto, and avoiding a temperature difference between the heat-generating devices.

Specifically, the water distributor 40 is provided with a water distribution groove 41. An opening of the water distribution groove 41 is adapted to the size and shape of the liquid outlet 12. The opening wall of the opening of the water distribution groove 41 is in a sealed connection with an opening wall of the liquid outlet 12. In this way, the inner periphery of the liquid outlet 12 does not have a structure such as a corner that will form a reservoir effect on water, so that all the water produced by condensation can flow into the water distribution groove 41, and then flow into each liquid return pipe 23 uniformly, thereby ensuring that the amount of the liquid in each heat dissipation plate 21 that participates in heat absorption and cooling of the heat-generating devices are the same, so that the cooling effects on the heat-generating devices are the same, and temperature differences are avoided.

Still referring to FIG. 1 and FIG. 2, in addition, based on any one of the foregoing embodiments, in an optional embodiment, the condenser 10 includes a condenser housing 13 and a plurality of condensing plates 14. The plurality of condensing plates 14 are disposed inside the condenser housing 13 side by side and spaced apart in the width direction. A condensing flow channel 15 is formed between two adjacent condensing plates 14. The high-temperature gas flows into the condenser housing 13 and exchanges heat with the condensing plate 14. The condensing plate 14 absorbs heat and dissipates the heat to the external environment through the condenser housing 13, and the gas is cooled to be condensed into water.

Alternatively, as an alternative to the above embodiment, the condenser 10 includes a condenser housing 13 and a plurality of condensing plates 14. The plurality of condensing plates 14 are arranged side by side and spaced apart in the width direction inside the condenser housing 13. A condensing flow channel 15 is formed between two adjacent condensing plates 14. An accommodating cavity is formed in each condensing plate 14. A flowable cooling medium is arranged in the accommodating cavity. The difference from the above embodiments is that the heat exchange occurs between the cooling medium contained in the condensing plates 14 and the gas, thereby achieving heat absorption and cooling of the gas and condensing the gas into water.

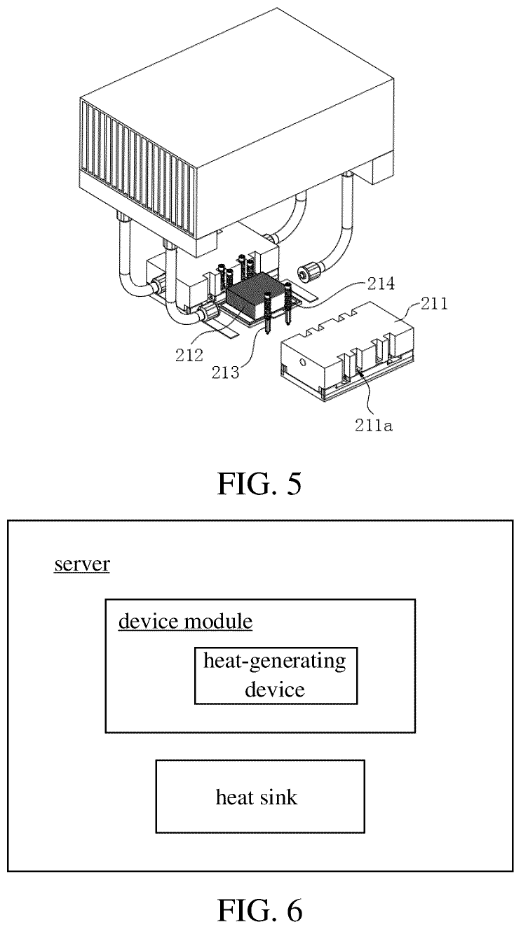

Still referring to FIG. 5, in an embodiment, the heat dissipation plate 21 includes a heat dissipation housing 211 and at least two heat dissipation fins 212. A mounting cavity is formed in the heat dissipation housing 211. The at least two heat dissipation fins 212 are mounted in the mounting cavity and are arranged side by side and spaced apart in a width direction, and a liquid flow channel is formed between two adjacent heat dissipation fins 212.

During use, the heat dissipation housing 211 is directly attached to the to-be-cooled chip or is in indirect contact with the to-be-cooled chip by using a heat transfer medium (for example, a thermally conductive adhesive), so that high-temperature heat generated by the chip during operation can be conducted to the heat dissipation housing 211, the heat is further conducted to the heat dissipation fins 212 for heat exchange with the cooling liquid in the mounting cavity. The cooling liquid absorbs the heat and heats up, and is vaporized into a gas, to cool the chip. The high-temperature gas produced flows into the condenser 10, to be recondensed into the cooling liquid, which then flows back into the heat dissipation housing 211, thereby realizing recycling and continuous heat dissipation of the chip.

Further, the heat dissipation plate 21 further includes a mounting assembly. The mounting assembly includes a mounting member 213 and an elastic member 214. The heat dissipation housing 211 is provided with a mounting through hole 211a. The mounting member 213 movably extends through the mounting through hole 211a, and the elastic member 214 is positioned between and abuts against the heat dissipation housing 211 and the mounting member 213.

Therefore, the heat dissipation plate 21 can be mounted on a main plate by using the mounting assembly, so that the heat dissipation housing 211 cooperates with the chip in heat transfer.

Specifically, the mounting member 213 movably extends through the mounting through hole 211a and is connected and fixed to the main plate. In this case, the elastic member 214 is compressed and stores energy; when the heat dissipation plate 21 is removed, the mounting member 213 is released from the main plate, so that the elastic member 214 releases the elastic force to enable the mounting member 213 to move away from the main plate automatically.

For example, the mounting member 213 is a threaded component such as a screw or a bolt to reduce the difficulty of mounting and dismounting and ensure the connection strength.

In an embodiment, a plurality of, such as four, mounting assemblies are provided. The four mounting assemblies are arranged at the periphery of the heat dissipation housing 211 in a rectangular shape, thereby further improving the connection reliability by increasing the number of connection positions with the main plate.

In addition to the above, the present disclosure further provides a server. As shown in FIG. 6, the server includes a device module including a heat-generating device, and a heat sink. The heat sink cooperates with the heat-generating device in heat transfer. The heat sink includes at least two heat dissipation modules 100. The at least two heat dissipation modules 100 are arranged side by side in a preset direction.

A functional device module specifically includes a main plate and a chip. The chip may serve as the heat-generating device. The chip is mounted on the main plate.

A plurality of chips may be arranged in an array on the main plate. Therefore, the heat sink formed by the at least two heat dissipation modules 100 can simultaneously meet heat dissipation and cooling requirements of the plurality of chips.

The heat dissipation module, the heat sink, and the server according to the present disclosure, can have improved heat dissipation capability and good heat dissipation uniformity, solving the problems of limited heat dissipation capability and poor heat dissipation uniformity.

In the present disclosure, the heat dissipation assemblies are respectively in heat transfer connection with the corresponding heat-generating devices, then the at least two heat dissipation assemblies are mounted side by side and spaced apart on one side of the condenser, the gas outlet pipe of each heat dissipation assembly connects the corresponding heat dissipation plate to the gas inlet, and the liquid return pipe connects the corresponding heat dissipation plate to the liquid outlet. in this way, when the heat-generating devices generate high-temperature heat during operation, the heat is transferred to the heat dissipation plate, so that the liquid phase change working medium in the heat dissipation plate absorbs the heat and then heats up and is vaporized into high-temperature gas, and the high-temperature gas flows into the condenser through the gas outlet pipe. As the high-temperature gas flows in the condenser, the condenser exchanges heat with the high-temperature gas so that the heat can be dissipated into the external environment, the gas cools down and recondenses into the liquid phase change working medium. The liquid phase change working medium flows into the liquid return pipe through the liquid outlet, and finally flows back into the heat dissipation plate. The above working process is cycled and repeated, so that the continuous cooling of the heat-generating devices can be realized, the heat dissipation effect on the heat-generating devices is enhanced, and the heat dissipation requirements are met. In addition, since the phase change working medium flows in from one end of the condenser and flows out from the other end of the condenser, the size in the length direction of the condenser is fully utilized, the flow path of the phase change working medium is extended, so that the more sufficient heat exchange between the phase change working medium and the condenser is enabled. The heat dissipation assemblies have the same heat dissipation performance. Therefore, the heat dissipation effect on the corresponding heat-generating devices is substantially the same, ensuring uniform heat dissipation and avoiding temperature differences between the heat-generating devices.

The technical features of the above embodiments may be combined arbitrarily, and in order to make the description concise, not all possible combinations of the technical features in the above embodiments are described, however, as long as there is no contradiction between the combinations of these technical features, it should be considered as falling within the scope of the present specification.

The above embodiments only illustrate several implementations of the present disclosure, and the description thereof is specific and detailed, but cannot be understood as a limitation to the patent scope. It should be noted that for those of ordinary skill in the art, several variants and improvements can be made without departing from the concept of the present disclosure, which all fall within the protection scope of the present disclosure. Therefore, the protection scope of the claims shall be subject to the appended claims.

1. A heat dissipation module, comprising:
a condenser provided with a gas inlet and a liquid outlet, wherein the gas inlet and the liquid outlet are respectively arranged at two opposite ends of the condenser in a length direction of the heat dissipation module, a phase change working medium in the condenser flows in a same direction as the length direction, and is directed from the gas inlet to the liquid outlet; and
at least two heat dissipation assemblies, wherein the at least two heat dissipation assemblies are arranged side by side on a side of the condenser in a width direction of the heat dissipation module; each heat dissipation assembly comprises a heat dissipation plate, a gas outlet pipe and a liquid return pipe; an end of the gas outlet pipe is in communication with a gas outlet of the heat dissipation plate, another end of the gas outlet pipe is in communication with the gas inlet; an end of the liquid return pipe is in communication with the liquid outlet, another end of the liquid return pipe is in communication with a liquid return port of the heat dissipation plate; and the heat dissipation assembly is configured to be in heat transfer connection with a heat-generating device.

2. The heat dissipation module according to claim 1, further comprising a gas distributor mounted at the gas inlet, and an end of each gas outlet pipe away from the heat dissipation plate is connected to the gas distributor.

3. The heat dissipation module according to claim 2, wherein the gas distributor is provided with a gas equalizing groove, an opening of the gas equalizing groove is adapted to a size and a shape of the gas inlet, and an opening wall of the opening of the gas equalizing groove is in a sealed connection with an opening wall of the gas inlet.

4. The heat dissipation module according to claim 1, further comprising a water distributor mounted at the liquid outlet, and an end of each liquid return pipe away from the heat dissipation plate is connected to the water distributor.

5. The heat dissipation module according to claim 4, wherein the water distributor is provided with a water distribution groove, an opening of the water distribution groove is adapted to a size and a shape of the liquid outlet, and an opening wall of the opening of the water distribution groove is in a sealed connection with an opening wall of the liquid outlet.

6. The heat dissipation module according to claim 1, wherein the condenser comprises a condenser housing and a plurality of condensing plates, the plurality of condensing plates being arranged side by side and spaced apart in the width direction inside the condenser housing, and a condensing flow channel is formed between two adjacent condensing plates.

7. The heat dissipation module according to claim 1, wherein the condenser comprises a condenser housing and a plurality of condensing plates, the plurality of condensing plates being arranged side by side and spaced apart in the width direction inside the condenser housing; a condensing flow channel is formed between two adjacent condensing plates, an accommodating cavity is formed in each condensing plate; and a flowable cooling medium is arranged in the accommodating cavity.

8. The heat dissipation module according to claim 1, wherein each heat dissipation plate comprises a heat dissipation housing and at least two heat dissipation fins, wherein a mounting cavity is formed in the heat dissipation housing; the at least two heat dissipation fins are mounted in the mounting cavity and arranged side by side and spaced apart in the width direction; and a liquid flow channel is formed between two adjacent heat dissipation fins.

9. The heat dissipation module according to claim 8, wherein the heat dissipation plate further comprises a mounting assembly comprising a mounting member and an elastic member; the heat dissipation housing is provided with a mounting through hole; the mounting member movably extends through the mounting through hole; and the elastic member is positioned between and abuts against the heat dissipation housing and the mounting member.

10. A heat sink, comprising at least two heat dissipation modules according to claim 1, wherein the at least two heat dissipation modules are arranged side by side in a preset direction.

11. A server, comprising:
a device module comprising a heat-generating device; and
the heat sink according to claim 10, wherein the heat sink cooperates with the heat-generating device in heat transfer.
